(19) United States
(12) Patent Application Publication
(10) Pub. No.: US 2011/0211676 A1
(43) Pub. Date: Sep. 1, 2011

(54) METHOD AND APPARATUS FOR APPLYING MATERIAL TO A SURFACE OF AN ANODE OF AN X-RAY SOURCE, ANODE AND X-RAY SOURCE

(75) Inventors: Ralf Dorscheid, Kerkrade (NL); Gereon Vogtmeier, Aachen (DE); Rainer Pietig, Herzogenrath (DE)

(73) Assignee: KONINKLIJKE PHILIPS ELECTRONICS N.V., EINDHOVEN (NL)

(21) Appl. No.: 12/672,306

(22) PCT Filed: Aug. 4, 2008
(86) PCT No.: PCT/IB08/53102

§ 371 Date: Feb. 5, 2010

(30) Foreign Application Priority Data
Aug. 8, 2007 (EP) 07114020.6

(51) Int. Cl. H01J 35/08; C23C 14/30; C23C 14/14; B05C 9/12

(52) U.S. Cl. 378/121; 378/143; 427/596; 427/597; 118/620

(57) ABSTRACT

A method and an apparatus for locally applying material to the surface of an anode of an X-ray source as well as a corresponding anode is presented. Anode material such as a repair material for filling a recess (121) in an X-ray emitting surface (115) is applied to the X-ray emitting surface of an anode (101). The location where such material is to be applied may be detected using a laser beam (133). The applied repair material including particles (41) of anode material such as tungsten, rhenium or molybdenum, is subsequently locally sintered using a high-energy laser beam (151). The sintered material may then be melted using a high-energy electron beam (163). Using such method, a damaged surface of an anode may be locally repaired. Alternatively, structures of different anode materials or of protrusions having different levels can be provided on the X-ray emitting surface (115) in order to selectively manipulate the X-ray emitting characteristics of the anode (101).

### FIELD OF THE INVENTION

The present invention relates to a method and an apparatus for applying material to a surface of an anode of an X-ray source. Particularly, the present invention relates to a method and an apparatus for repairing an anode of an X-ray source or for providing a surface structure at a surface of an anode of an X-ray source. Furthermore, the present invention relates to an anode having specific electron optical properties and to an X-ray source comprising such anode.

### TECHNICAL BACKGROUND

X-ray sources are used in a wide variety of applications such as medical applications where for example two-dimensional or three-dimensional images of a patient to be examined can be obtained using X-ray projection and corresponding X-ray detectors. In the X-ray source, a beam of accelerated electrons is directed to a surface of an anode. When impacting on the anode, the electrons are decelerated while emitting X-rays.

The structure of an X-ray emitting surface of an anode may be critical for the X-ray emitting properties of the anode in an X-ray source.

For example, after a certain period of time, the focal track of the electron beam on the surface of the anode of the X-ray tube may have been loaded with thermal and/or mechanical stress such that damages at the surface of the anode may occur. Such damages can be visible changes like e.g. cracks within the focal track. Due to such damages, the X-ray beam may start flickering more and more and hence the intensity of the X-ray beam may vary in an unpredictable way.

In particular, the thermal stress induced by the electron beam impacting onto the anode's surface may cause melt-down phenomena wherein the melt down effects may poison the vacuum and tube arching may be increased drastically.

Currently, in order to repair a damaged anode, the top-layer of the focal track on the anode's surface is usually removed e.g. by grinding off the damaged layer. Therein, the thickness of the removed layer of anode material is in the same order as the depth of the metallurgical defects. This removal procedure can be repeated several times.

However, according to this standard repair method, material is usually ablated at a complete X-ray emitting surface of the anode while in principle only specific locations on the focal track are actually damaged and only these locations would have to be repaired. Furthermore, the conventional ablation process of material in order to smoothen the anode's surface can be repeated only a few times unless the total thickness of the anode at the focal track becomes too small. Furthermore, as the total thickness of the anode is reduced by the conventional repairing method, the electron optics within the X-ray source may have to be adapted to the changing position of the anode's X-ray emitting surface after each repairing process.

Accordingly, there may be a need for an improved method and an improved apparatus for providing material to a surface of an anode, especially for repairing an anode of an X-ray tube, which overcomes the above-described deficiencies of the state-of-the-art at least in part.

Furthermore, conventional anodes for X-ray sources usually have a flat or even X-ray emitting surface consisting of a single material. E.g., the X-ray emitting surface can conventionally be provided by homogeneously sputtering heavy metal onto the surface of a substrate. Accordingly, the anode has similar X-ray emission characteristics along its entire X-ray emitting surface.

However, there may be a need to provide an anode and a method or an apparatus for preparing such anode for an X-ray source wherein the anode has an X-ray emitting surface having various differing X-ray emission characteristics at different locations along the X-ray emitting surface.

### SUMMARY OF THE INVENTION

At least parts of the above described needs may be met by the subject-matter according to the independent claims. Advantageous embodiments of the present invention are described in the dependent claims.

According to a first aspect of the present invention, a method for locally applying material to a surface of an anode of an X-ray source is proposed, the method comprising: determining of surface regions of the anode where material is to be applied; applying material at the determined surface regions; selective local sintering of the applied material by local illumination with a laser beam at the determined surface regions; and, optionally, melting of the sintered material.

The first aspect of the present invention may be seen as being based on the idea that anode material can be applied to an anode only at the necessary positions where new material is needed such as for example in surface cavities or recesses which may occur as a result of continuous thermal and mechanical stress or at specific locations on the anode's surface in order to provide a structured anode surface. For this purpose, the anode material may be first applied to the anode's surface and subsequently be sintered and thereby adhered to the surface by locally heating using a laser beam.

The gist of the method according to the first aspect of the invention may be seen in the fact that, first, regions where material is to be applied such as damaged surface regions of the anode where there are for example cavities or recesses in the surface are determined; second, material such as repair material or additional anode material is applied at the determined regions such as onto or into the damaged surface region; and, third, the applied material is locally sintered using a laser beam and subsequently, optionally, melted using e.g. a high-energy beam.

Accordingly, it is possible to apply material only at local regions of the surface of the anode where the anode is e.g. damaged or is to be structured. Compared with abrasing the entire anode's surface and subsequently replacing the entire anode surface layer (e.g. by chemical vapour deposition, CVD), repair material can be saved as only the damage recesses or cavities have to be filled with repair material. As the repair material such as heavy metals like tungsten, rhenium or molybdenum, can be very expensive, costs can be saved by applying the method according to the first aspect of the invention.

Furthermore, by only filling the damaged recesses with repair material, sintering and subsequently melting it, the original surface of the anode may be re-established. Accordingly, after repairing the anode, it can be mounted into the original X-ray source and it is not necessary e.g. to re-calibrate the X-ray source and its electron optics.

Furthermore, with the method according to the first aspect, an anode having a structured surface can be prepared. By locally applying anode material to the anode's surface, e.g. bumps of different height can be formed at the surface of the anode whereby electron optical properties of the anode can be locally influenced. Alternatively, different anode materials can be applied at different locations on the anode's surface in order to influence the X-ray radiation emitted from the respective anode surface regions.

In the following, possible features, advantages and embodiments of the method according to the above first aspect will be explained in detail.

The anode for the X-ray source may comprise, at least at its surface which, when installed in the X-ray source, is subjected to the electron beam (herein also referred as X-ray emitting surface), a heavy metal such as tungsten, rhenium or molybdenum. For example, the anode may be a circular disk having an X-ray emitting surface at its circumferential border. For example, a circumferential surface of the disk-shaped anode may be slanted at an angle such that an electron beam coming from the cathode may impact onto the X-ray emitting surface such that the directions of the electron beam and the resulting X-ray beam may be approximately perpendicular to each other. Such disk-shaped anode may be rotated during operation of the X-ray tube such that the location of electron impact onto the anode's surface (herein also referred as focal track) moves along the circular circumference of the anode.

There may be different reasons why anode material may have to be applied or deposited at the anode's surface. E.g., the X-ray emitting surface of the anode may be damaged after a continuous operation of the X-ray source in that recesses or grooves are formed within the surface. These damages can be detected taking for example the undamaged anode surface region as a reference.

After having detected one or several or all of the damaged surface regions, repair material may be applied onto or into some or each of the detected regions. Therein, the repair material can be applied over the entire anode surface or parts thereof or it can be applied selectively only onto/into the detected damaged surface region. As will be described further below, the process of applying material can be performed in a variety of different ways.

The applied material can then be locally sintered by the so-called selective laser sintering (SLS) process. Therein, particles of anode material can be locally sintered by illumination with a high-energy laser beam. Typical lasers used for this purpose may be pulsed laser sources or permanent laser sources e.g. CO₂ Laser and Eximer Laser.

The selective laser sintering (SLS) may be defined as an additive rapid manufacturing or repairing technique that involves using a high power laser to fuse together small particles of plastic, metal or ceramic powders into a mass representing e.g. a desired three-dimensional object. For manufacturing purposes, the laser selectively may fuse powdered material by scanning cross-sections generated e.g. from a 3D digital description of a part to be manufactured (e.g. from a CAD-file) on the surface of a powder bed. After each cross-section is scanned, the powder bed is lowered by one layer thickness, a new layer of material is applied on top and the process is repeated until the desired part is completed.

Compared to other methods, a relatively wide range of powder materials can be processed. Commercially available materials include polymers, metals (tungsten, molybdenum, etc.). The physical process can be full melting, partial melting, liquid-phase sintering, and depending on the material up to 100% density can be achieved and material properties comparable to those from conventional manufacturing methods.

According to an embodiment of the present invention, after the selective sintering step, the sintered material is melted e.g. by applying a high-energy beam such as for example an electron beam or a high-energy laser beam. This melting step may serve for increasing the density of the pre-sintered material. Therein, the pre-sintered material may be completely liquefied or partially be liquefied. Subsequently, the liquefied material re-solidifies thereby creating preferably a smooth surface on the anode surface.

The melting step can be performed directly after applying and sintering the material onto/into each respective predetermined surface region or, alternatively, all predetermined or damaged surface regions can be covered or filled first with material which is pre-sintered onto the surface region and then the entire anode may be subjected to a suitable melting step. For this purpose, the anode may be placed into a separate apparatus such as for example a high temperature furnace or, more preferred, an apparatus for locally melting the pre-sintered material for example by applying a high-energy beam such as an electron beam or a high-energy laser beam. For example, the melting step may be performed within the actual X-ray tube wherein the energy of the electron beam usually used for creating the X-ray beam is increase in order to have sufficient energy for locally melting the pre-sintered material.

Especially in case the laser power of the laser used for the selective laser sintering is high enough to implement material with a density of approximately 100% including the integration to its border materials and if the accuracy of the optics with which the new heavy material is applied to its position is high, the melting step is not necessary. The applied material can then be directly melted with the SLS laser.

According to an embodiment of the present invention, the repair material is applied in the form of a fluid containing small particles. In this context, a fluid may be defined as a material being able to flow or to be sprayed. Such fluid may be provided as a powder or as an emulsion or paste in which small particles are dispensed in a liquid solution. The size of the particles may be adapted such that typical recesses in a damaged anode's surface may be substantially completely filled with repair material. Typical particle sizes are in the range of between approximately 100 nm and 2 μm. The particles may comprise a material similar to the material of the original anode surface such as a heavy metal like tungsten, rhenium, molybdenum or a compound or alloy thereof.

The fluid may be applied to the anode surface in a variety of different ways. For example, the fluid may be sprinkled or printed locally onto the anode's surface. Alternatively, the fluid may be applied to the predetermined surface region by first applying, e.g. sprinkling, the fluid over the surface region and then distributing the fluid using for example a squeegee. By using such squeegee, the steps of determining damaged surface regions and of applying the repair material can be more or less combined into one single step, as the squeegee may push the fluid automatically into damage recesses in the anode's surface while shoveling or wiping excessive repair material over the anodes surface. The repair material may be sprinkled, printed or sprayed onto the damaged anode surface and by then distributing the repair material using the squeegee, recesses in the damaged surface region are preferably filled with the repair material.

According to a further embodiment of the present invention, the determination of the region where material is to be applied is performed by optically detecting damaged surface regions. For this purpose, light coming from a light source such as for example a laser or an LED may be directed to the surface of the anode to be treated or repaired. The light may be focused to a small spot. The spot may be scanned along the anode's surface. From the light reflected from the surface of the anode, the position, shape and/or volume of recesses in the damaged surface region may be detected. For detecting the depth of a recess, the light source and the anode's surface can be arranged in order to form an arrangement similar to an interferometer.

By optically detecting the damaged surface regions, recesses or grooves in the anode's surface can be reliably and precisely detected without mechanically contacting the surface thereby avoiding any contamination.

Furthermore, according to an embodiment, the same laser beam can be used for detecting of damaged surface regions as for the selective laser sintering. Thereby, the number of necessary light sources can be reduced. Additional optics between the laser and the anode's surface may be provided.

According to a further embodiment, a volume of one recess or of a combination of all recesses in the damaged surface region may be determined, preferably in advance to applying the repair material. Knowing such volume, the necessary amount of repair material can be determined.

According to a further embodiment, repair material can be locally applied in accordance with the volume of a local recess detected in a previous detection step. Knowing the volume of a recess in the damaged surface region, a substantially corresponding volume or a slightly excessive volume of repair material can be applied into the recess. Accordingly, repair material can be applied in a sufficient but not excessive amount such that no expensive repair material is wasted.

According to a further embodiment, a sequence of applying material onto or into the determined surface regions and subsequently selective sintering of the applied material is repeated several times. Accordingly, layers of material can be applied onto the anode's surface one after the other. For example, first a thin layer of repair material having a thickness of a few micrometer, the layer thickness depending on the used material and here the average particle size, may be applied to a damaged surface, then be sintered and then a next layer of repair material can be applied and sintered until the original surface of the anode is re-established. Thereby, even deep recesses within the anode's surface can be filled with sintered repair material. E.g. while using a material with an average material particle size of 1 μm the layer thickness may be roughly 3 times higher.

According to a further embodiment, the sintered material is melted by locally applying a high-energy beam such as for example an electron beam or a high-energy laser beam. While the pre-sintered repair material may still have small cavities therein and therefore have no optimal density, after melting, a repair material will solidify substantially without cavities and having an optimal density. In order to only locally melt the pre-sintered repair material, a focused beam of electrons or light may be applied to the respective damaged regions of the anode's surface which have previously been filled with repair material. When the beam has a sufficiently high-energy, the repair material will locally melt, flow and fill remaining cavities therein and then re-solidify.

Optionally, after melting the repair material, the surface of the repaired anode may be surface finished for example by polishing. Thereby, a defined height of the repaired anode surface may be achieved such that it exactly matches the height of the original new anode.

According to a further embodiment, different materials are applied and locally sintered at different locations at the surface of the anode. In this way, an anode may be prepared which has different regions comprising different X-ray emitting material. For example, some surface regions may comprise tungsten while other regions may comprise rhenium. When e.g. a disk-shaped anode is rotated in operation, these different regions will subsequently be subjected to the impacting electron beam. Accordingly, there will be times when X-rays are emitted from the tungsten surface while, in other times, the rhenium surface emits X-rays. As these different materials emit different spectra of X-rays, the emitted X-ray spectrum may vary in dependence of time. Using e.g. X-ray detectors which are able to distinguish different X-ray spectra, additional information can be derived from the X-ray projections.

According to a further embodiment, material is applied and locally sintered at different locations at the surface of the anode in different amounts such that a relief structured anode surface results. Such relief structured anode may have no even X-ray emitting surface but may have predetermined structures of anode material protruding from the X-ray emitting surface. Due to such structures, the electron optical properties and/or the X-ray optical properties of the anodes surface may be varied locally. Accordingly, e.g. when a disk-like anode having such non-even X-ray emitting surface is rotated during operation of the X-ray tube, an X-ray beam having time-dependent focusing properties may be obtained.

According to a further aspect of the present invention, an apparatus for locally applying material to an anode of an X-ray source is provided, the apparatus comprising a holder for holding the anode; an applying mechanism adapted for applying material at predetermined regions at the surface of the anode and a laser adapted for locally sintering the applied material.

The apparatus may be adapted for performing the method according to the above first aspect of the invention.

All of the holder, the applying mechanism and the laser may be included in one single chamber. The anode to be prepared or repaired can then be brought into the chamber and can be installed at the holder. Locations where anode material is to be applied can be predetermined. E.g. damages in a surface of the anode can be detected using a detector such as an optical detector and repair material can be applied onto/into the damages using the applying mechanism. Subsequently, the repair material can be locally sintered using the laser a focal spot of which can be directed onto the applied repair material in the damaged surface regions.

According to an embodiment of the invention, the apparatus further comprises a high-energy beam source adapted for locally melting sintered material. This high-energy beam source may comprise for example an electron beam source providing a beam of accelerated electrons which can be focused onto the pre-sintered material. The high-energy beam source can be provided in the same chamber as the other components of the apparatus. Alternatively, there may be provided a second chamber including the high-energy beam source such that the anode can be first inserted and treated within the first chamber for applying and pre-sintering the repair material and can then be transferred to the second chamber for melting the pre-sintered repair material locally using the high-energy beam source. Alternatively, the two chambers can be provided in two separate devices.

According to a further embodiment, the holder is adapted for rotating the anode around a central rotation axis. For example in the case of a disk-shaped anode to be repaired, the holder may be adapted such that the anode can be rotated around the middle axis of the disk. While rotating the anode using the holder, the X-ray emitting surface provided at the circumference of the anode disk can be rotated 360° along a circular line such that each point on the X-ray emitting surface can be subjected to the applying mechanism, the laser and an optional detector, all of them being installed in a fixed location with respect to the circumferential line of the anode. Accordingly, the entire X-ray emitting surface of the anode can be prepared or repaired simply by rotating the anode and it is not necessary to move any of the applying mechanism, the laser or the detector.

According to a further embodiment, the apparatus further comprises a detector for detecting damages such as holes or recesses in a surface of the anode. The detector may comprise a light source and a light detector adapted for optically detecting at least one of a position, a volume and a depth of the damage in a surface of the anode. Accordingly, the apparatus may be adapted for optically and contactlessly detecting the regions where the applying mechanism is to apply material.

According to a further embodiment of the present invention, the applying mechanism is adapted for applying a fluid containing small material particles by at least one of sprinkling, printing and spraying onto the surface of the anode. Therein, the applying mechanism may be adapted for selectively locally applying the fluid directly in the damaged surface regions detected by the detector. The precision of such local application may be in the range of a few to a few hundred micrometers. The fluid can be dry like a powder or can be provided as a fluid emulsion including a liquid binder into which particles of an actual heavy metal anode material can be included.

Alternatively, the applying mechanism may be adapted for applying the repair material over the entire X-ray emitting surface and may have further means for distributing and introducing the repair material into recesses or grooves within the anode's surface. For example, a squeegee may be provided for sliding on the surface of the anode to be repaired wherein the squeegee shovels or distributes previously applied material and preferably pushes it into the regions where it is needed.

According to a further embodiment of the present invention, the apparatus further includes a control for controlling at least one of the position, the size and the power of the lasering spot of the laser. For example, the laser can be controlled such that its lasering spot moves along the surface of the anode to be structured or repaired in a longitudinal or transversal direction such that the laser spot is scanned along the surface including e.g. damages detected by the detector. The power of the laser spot may be adapted such that all of the applied material provided at a specific location on the anode's surface can be sintered taking into account for example the thickness of the layer of applied material.

According to a further aspect of the present invention, an anode of an X-ray source is provided, the anode comprising a structured anode surface. The structured anode surface may be an X-ray emitting surface when the anode is operated in an X-ray tube. The structured anode surface may be formed using the method described above.

According to an embodiment, the relief structured anode surface may comprise a relief structure and may be non-even and may comprise one of a concave and a convex surface. The surface structure may be adapted to provide specific electron optical properties when the relief structured surface is subjected to an impacting electron beam. For example, protruding side walls at the X-ray emitting surface may focus the emitted X-rays.

According to a further embodiment, the relief structured anode surface comprises a symmetric structure. For example, there may be a mirror symmetry with respect to the focal track on a disk shaped anode.

According to a further embodiment, the structured anode surface comprises local surface regions consisting of different X-ray emitting materials. Accordingly, dependent on which of the local surface regions is irradiated with an electron beam, X-rays of different characteristics can be emitted.

According to a further aspect of the present invention, an X-ray tube is provided comprising an anode as described with respect to the previous aspect of the present invention.

It has to be noted that embodiments of the invention are described with reference to different subject matters. In particular, some embodiments are described with reference to the method while other embodiments are described with reference to the apparatus. However, a person skilled in the art will gather from the above and the following description that, unless other notified, in addition to any combination of features belonging to one type of subject matter also any combination between features relating to different subject matters is considered to be disclosed with this application.

The aspects defined above and further aspects, features and advantages of the present invention can be derived from the examples of embodiments to be described hereinafter and are explained with reference to the examples of embodiment. The invention will be described in more detail hereinafter with reference to examples of embodiment but to which the invention is not limited.

### BRIEF DESCRIPTION OF THE DRAWINGS

FIG. 1 schematically shows an X-ray tube arrangement comprising an anode.

FIGS. 2a to 2d schematically represent process steps of the method according to an embodiment of the present invention.

FIG. 3 shows a side view of an apparatus according to an embodiment of the present invention.

FIG. 4 shows a top view of the apparatus shown in FIG. 3.

FIG. 5 shows a cross sectional view of an anode having a relief structured X-ray emitting surface according to an embodiment of the invention.

FIG. 6 shows a perspective view of an anode with an X-ray emitting surface with different local regions according to an embodiment of the invention.

It is to be noted that the illustration in the drawings is schematically only and not to scale. Furthermore, in the various figures, similar or identical elements are provided with the same reference signs.

### DETAILED DESCRIPTION OF PREFERRED EMBODIMENTS

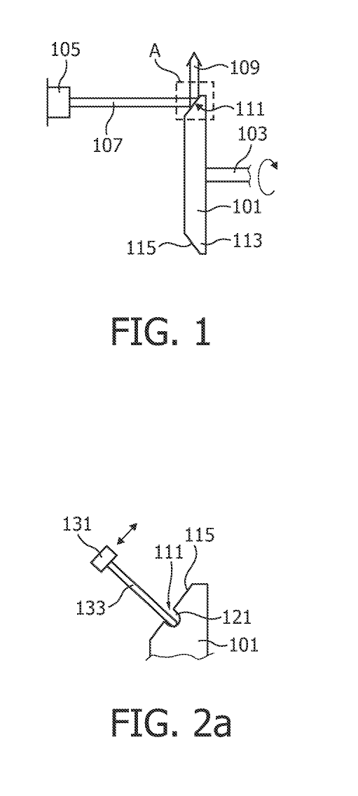

FIG. 1 shows an X-ray tube arrangement including disk-shaped anode 101 and an electron source 105. The anode 101 is disk-shaped and comprises a heavy metal such as tungsten, rhenium or molybdenum. At its circumferential border 113 the anode 101 comprises a slanted surface which acts as an X-ray emitting surface 115 for emitting an X-ray beam 109 when irradiated by an electron beam 107 coming from the electron source 105. At the focal track 111 where the electron beam 107 impacts onto the X-ray emitting surface 115, cracks or recesses may occur after continuous operation of the X-ray tube.

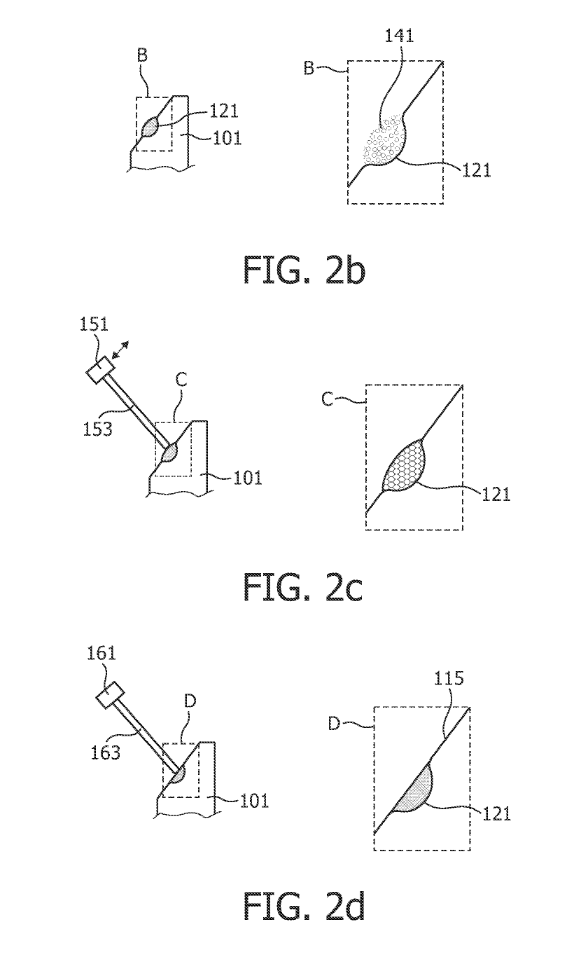

FIGS. 2a to 2d show the region A in the neighbourhood of the focal track 111 as indicated in FIG. 1 during different process steps of an embodiment of the method according to the present invention.

As shown in FIG. 2a, a recess 121 formed on the focal track 111 may be detected and its depth may be measured using a laser beam 133 coming from a first laser 131. As indicated by the arrow in FIG. 2a, the laser beam 133 or the laser 131 itself may be scanned transversely along the X-ray emitting surface 115 while the anode 101 is rotated as indicated in FIG. 1. Accordingly, the entire X-ray emitting surface 115 can be scanned for damages in the form of recesses by the laser beam 133.

FIG. 2b shows the recess 121 after repair material has been applied thereto. As can be seen in the enlarged illustration of the region B, a powder including particles 141 of repair material has been applied to the region of the recess 121. As excessive repair material is provided, the fluid comprising the particles 141 slightly protrudes from the recess 121.

In a subsequent process step as shown in FIG. 2c, the particles 141 are sintered using a high-energy laser 151. Also this laser 151 or the laser beam 153 can be scanned along the X-ray emitting surface 115 of the anode 101 such that the entire X-ray emitting surface 115 can be reached. By sintering the repair material within the recess 121, the particles 141 adhere to each other and to the surface within the recess 121. However, cavities within the sintered repair material may remain.

In a further process step as shown in FIG. 2d, a high-energy electron beam 163 originating from an electron source 161 is directed to the previously sintered repair material. The electron beam 163 has such high energy that the heavy metal particles of the repair material melt. Accordingly, the cavities previously present in the sintered repair material will disappear and after re-solidification of the repair material, the recess 121 is preferably completely filled with repair material having an optimum density. As the volume of the recess 121 has been previously measured using the laser 131 (see FIG. 2a), the amount of repair material applied to the recess 121 can be adapted such that after re-solidification the recess 121 may be completely filled but preferably no repair material protrudes above the X-ray emitting surface 115.

Optionally, in a final process step, the X-ray emitting surface 151 can be polished.

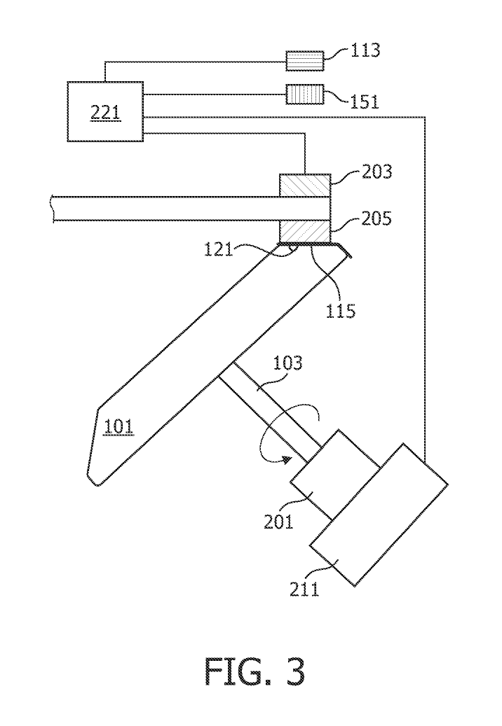

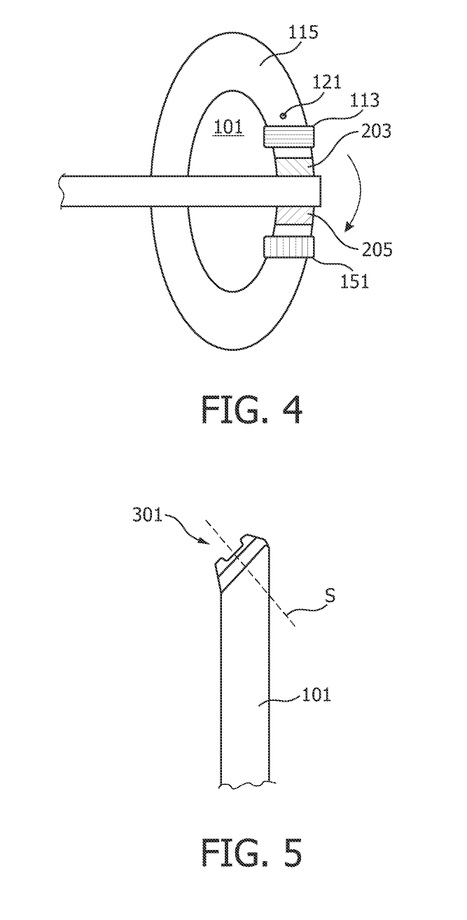

FIGS. 3 and 4 schematically show an apparatus for applying material to an anode 101 of an X-ray source in side view (FIG. 3) and top view (FIG. 4). An anode 101 can be held with its shaft 103 mounted to a holder 201. The holder 201 is adapted to rotate the anode 101 around its shaft 103 as indicated by the arrow in FIG. 3.

During rotation of the anode 101, a specific location at which a recess 121 is present first passes the laser 113. The laser beam scans the X-ray emitting surface 115 for detecting the recess 121 and preferably measuring its volume.

While further rotating the anode 101, the recess 121 reaches a mechanism 203 for applying repair material to the X-ray emitting surface 115. The applying mechanism 203 sprinkles powder including particles of repair materials onto the X-ray emitting surface 115.

While further turning, the location of the recess 121 reaches a squeegee 205 which levels and wipes off excessive repair material powder.

Turning further, the recess 121 being filled with repair material particles 141 reaches the high-energy laser 151 which, knowing the location of the recess 121 detected by the first laser 113, may irradiate the previously deposited repair material powder in order to sinter the repair material particles.

After sintering the repair material and therefore adhering it to the surface of the anode 101, the anode 101 can be removed from the apparatus for applying the repair material and can be installed in a further apparatus or, optionally, in the original X-ray tube, where a high-energy electron beam can be directed to the X-ray emitting surface 115. Using such high-energy electron beam, the previously sintered repair material can be melted in order to obtain an optimum density and a smooth surface at the side of the repaired recess 121.

Alternatively, the an electron beam source may be provided within the apparatus for applying the material itself such that the material can be melted directly after applying and sintering it. In such arrangement, the anode does not need to be removed and be installed in a further apparatus for the local melting procedure but can be repaired within a single apparatus which is adapted to perform all process steps.

All of a motor 211 driving the rotatable holder 201, the mechanism 203 for applying the material, the laser 113 for detecting the recess 121 and the laser 151 for locally sintering the applied material and, optionally, the electron beam source are connected to a control 221 adapted for controlling for example the position, size and power of a lasering spot of the laser 151 for sintering the material based on the detection result of the detection laser 113. For clarity purposes, the control 221 is not shown in FIG. 4.

In FIG. 5, the cross-section of a disk-shaped anode 101 with a relief structured surface 301 is shown schematically. The relief structured surface 301 comprises a concave surface structure being symmetrical with respect to an axis S perpendicular to the slanted circumferential surface of the anode. Thereby, a focussing effect can be obtained for the X-ray emitted from such anode surface.

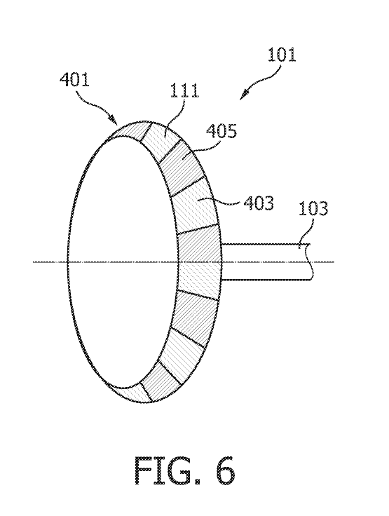

FIG. 6 shows a disk-shaped anode with a structured surface 401 having surface regions 403, 405 comprising different X-ray emitting materials. Due to the alternating arrangement of the different surface regions 401, 403, a timely varying X-ray is emitted when the anode 101 is rotated around its axis 103 while being irradiated with an electron beam onto the focal track 111.

In a non-limiting attempt to recapitulate the above-described embodiments of the present invention one could state: A method and an apparatus for locally applying material to the surface of an anode of an X-ray source as well as a corresponding anode is presented. Anode material such as a repair material for filling a recess 121 in an X-ray emitting surface 115 is applied to the surface of an anode 101. The location where such material is to be applied may be detected using a laser beam 133. The applied repair material including particles 141 of anode material such as tungsten, rhenium or molybdenum, is subsequently locally sintered using a high-energy laser beam 151. The sintered material is then melted using a high-energy electron beam 163. Using such method, a damaged surface of an anode may be locally repaired. Alternatively, structures of different anode materials or of protrusions having different levels can be provided on the X-ray emitting surface 115 in order to selectively manipulate the X-ray emitting characteristics of the anode 101.

It should be noted that the term “comprising” does not exclude other elements or steps and the “a” or “an” does not exclude a plurality. Also elements described in association with different embodiments may be combined. It should also be noted that reference signs in the claims should not be construed as limiting the scope of the claims.

1. A method for locally applying material to a surface (115) of an anode (101) of an X-ray source, the method comprising:
determining of surface regions of the anode where material is to be applied;
applying material at the determined surface regions;
selective local sintering of the applied material by local illumination with a laser (151) beam at the determined surface regions.

2. The method of claim 1, further comprising melting of the sintered material.

3. The method of claim 1, wherein the material is applied in the form of a fluid containing small particles (141).

4. The method of claim 1, wherein the material is selected from one of tungsten, rhenium and molybdenum.

5. The method of claim 1, wherein the determining of surface regions of the anode where material is to be applied comprises optically detecting of damaged surface regions of the anode.

6. The method of claim 5, wherein the surface regions are detected using the same laser beam as for the selective sintering.

7. The method of claim 5, wherein the detecting of damaged surface regions of the anode comprises detecting of a volume of recesses in the damaged region.

8. The method of claim 7, wherein material is locally applied in accordance with the volume of a local recess (121).

9. The method of claim 1, wherein a sequence of applying material onto the determined surface regions and subsequently selective sintering of the applied material is repeated several times.

10. The method of claim 1, wherein the sintered material is melted by locally applying a high energy beam.

11. The method of claim 1, wherein different materials are applied and locally sintered at different locations at the surface of the anode.

12. The method of claim 1, wherein material is applied and locally sintered at different locations at the surface of the anode in different amounts such that a relief structured anode surface results.

13. An apparatus for locally applying material to an anode (101) of an X-ray source, the apparatus comprising:
a holder (201) for holding the anode;
an applying mechanism (203) adapted for applying material at predetermined regions at the surface (115) of the anode;
a laser (151) adapted for locally sintering the applied material.

14. The apparatus of claim 13, further comprising a high energy beam source adapted for locally melting sintered material.

15. The apparatus of claim 14, wherein the high energy beam source comprises an electron beam source.

16. The apparatus of claim 13, wherein the holder is adapted for rotating the anode around a central rotation axis.

17. The apparatus of claim 13, further comprising a detector for detecting damages in a surface of the anode.

18. The apparatus of claim 17, wherein the detector comprises a light source (131) and a light detector adapted for optically detecting at least one of a position, a volume and a depth of a damage in a surface of the anode.

19. The apparatus of claim 13, wherein the applying mechanism is adapted for applying a fluid containing small material particles by at least one of sprinkling, printing and spraying onto the surface of the anode.

20. The apparatus of claim 13, further including a control (221) for controlling at least one of the position, size and power of a lasering spot of the laser (151).

21. An anode (101) of an X-ray source, the anode comprising a structured anode surface (301, 401).

22. The anode of claim 21, wherein the structured anode surface (301, 401) is an X-ray emitting surface when the anode is operated in an X-ray tube.

23. The anode of claim 21, wherein the structured anode surface (301) comprises a relief with at least one of a concave and a convex surface.

24. The anode of claim 21, wherein the structured anode surface comprises a symmetric structure.

25. The anode of claim 21, wherein the structured anode surface (401) comprises local surface regions consisting of different X-ray emitting materials.

26. The anode of claim 1, wherein the relief structured anode surface is formed using the method for locally applying surface (115) of an anode (101) of an X-ray source, the method comprising:
determining of surface regions of the anode where material is to be applied;
applying material at the determined surface regions;
selective local sintering of the applied material by local illumination with a laser (151) beam at the determined surface regions.

27. An X-ray tube comprising an anode (101) according to claim 21.
